(19) United States
(12) Patent Application Publication
(10) Pub. No.: US 2019/0364688 A1
(43) Pub. Date: Nov. 28, 2019

(54) SEVER HAVING SLIDE RAIL FASTENING STRUCTURE

(71) Applicant: Super Micro Computer Inc., San Jose, CA (US)

(72) Inventors: Richard S. CHEN, San Jose, CA (US); Ken-Sheng LIN, San Jose (US); Shih-Hsing CHIEN, San Jose (US)

(21) Appl. No.: 15/988,966

(22) Filed: May 24, 2018

(51) Int. Cl. H05K 7/18

(52) U.S. Cl. CPC H05K 7/183

(57) ABSTRACT

A server having a slide rail fastening structure is provided. The server includes a rack, a support and a bracket. The rack includes two pillars and a slide rail assembly mounted to the two pillars. Each pillar includes multiple round holes. The support includes a body and includes a first plate and a second plate connected to the body. The first plate is fixed to one of the round holes of the corresponding pillar. The second plate includes a plurality of openings in a shape different from the round hole. The bracket has a first board and a second board perpendicularly connected to the first board, the first board is arranged corresponding to the first plate, the second board is arranged to the slide rail assembly and assembled to one end of the slide rail assembly.

### TECHNICAL FIELD

The present invention relates to a server and, in particular, to a server having slide rail fastening structure mounted to a pillar having different shaped positioning holes.

### BACKGROUND

A conventional server rack usually has round positioning holes on its pillars. However, the conventional server rack cannot match all types of chassis since chassis have various specifications. To solve this problem, a fastener, like a fastening plate, is used to convert a square hole to round hole, so that slide rails, chassis or other components can be mounted to the server rack. However, no fasteners are specially designed for a slide rail with a locking mechanism.

### SUMMARY

It is an objective of the present invention to provide a server having a slide rail fastening structure capable of converting positioning holes (e.g. converting a round hole to a square hole).

It is another objective of the present invention to provide a server having a slide rail fastening structure. The structure is simple and allows for easy assembly and easy manufacture at low costs.

Accordingly, the present invention provides a server having a slide rail fastening structure. The server has a rack, a support and a bracket. The rack includes two pillars and a slide rail assembly. The slide rail assembly is arranged longitudinally with respect to the rack and mounted to the two pillars. Each pillar includes a plurality of round holes spaced apart from each other. The support includes a body and includes a first plate and a second plate connected to the body at two sides thereof. The first plate is fixed to at least one of the round holes of a corresponding one of the pillars. The second plate includes a plurality of openings, the opening is of a shape different from the round hole and used to position the slide rail assembly. The bracket includes a first board and a second board perpendicularly connected to the first board, the first board is arranged corresponding to the first plate, the second board is arranged parallel to the slide rail assembly and assembled to one end of the slide rail assembly, and thereby the bracket and this end move together with respect to the rack.

According to one embodiment, the slide rail assembly includes a fixing plate, a resilient hook and an elastic element. The fixing plate includes a plurality of ports, the resilient hook is disposed adjacent to the fixing plate, and the elastic element is fixed to any of the ports, so that the slide rail assembly can be fixed to the second plate of the support. In another embodiment, the server further includes a coupling member coupled to an outer lateral surface of the slide rail assembly. The fixing plate and the resilient hook are disposed on the coupling member and are fastened to respective openings of the support, so that the slide rail assembly can be fixed to the pillar.

The first plate further includes a plurality of protruding flanges and a plurality of through holes penetrating the respective protruding flanges. The protruding flanges are inserted and engaged with the respective round holes. Fastening elements are inserted through the respective round holes and the respective through holes. Therefore, the slide rail assembly can be mounted to the rack having a different shaped positioning hole by means of the support.

In summary, the support and the bracket are used to convert shapes of the positioning holes, so that the slide rail assembly and chassis of different specifications can be assembled to the rack without the need of changing the present rack structure (e.g. the round hole or a different shaped positioning hole). The server has a simple slide rail fastening structure (i.e. the support and the bracket) which allows for easy assembly and manufacture at low costs.

### BRIEF DESCRIPTION OF THE DRAWINGS

The disclosure will become more fully understood from the detailed description and the drawings given herein below for illustration only, and thus does not limit the disclosure, wherein:

FIG. 1 is a schematic view illustrating a server having a slide rail fastening structure according to the present invention;

FIG. 2 is a perspective view illustrating the slide rail fastening structure mounted on one pillar;

FIG. 3 is another perspective view illustrating the slide rail fastening structure mounted on one pillar;

FIG. 4 is a perspective exploded view illustrating the slide rail fastening structure mounted on one pillar;

FIG. 5 is a cross-sectional view illustrating the slide rail fastening structure mounted on one pillar;

FIG. 6 is another cross-sectional view illustrating the slide rail fastening structure mounted on one pillar;

FIG. 7 is a perspective view illustrating a locking structure; and

FIG. 8 is a cross-sectional view illustrating the locking structure.

### DETAILED DESCRIPTION

Detailed descriptions and technical contents of the present disclosure are illustrated below in conjunction with the accompanying drawings. However, it is to be understood that the descriptions and the accompanying drawings disclosed herein are merely illustrative and exemplary and not intended to limit the scope of the present disclosure.

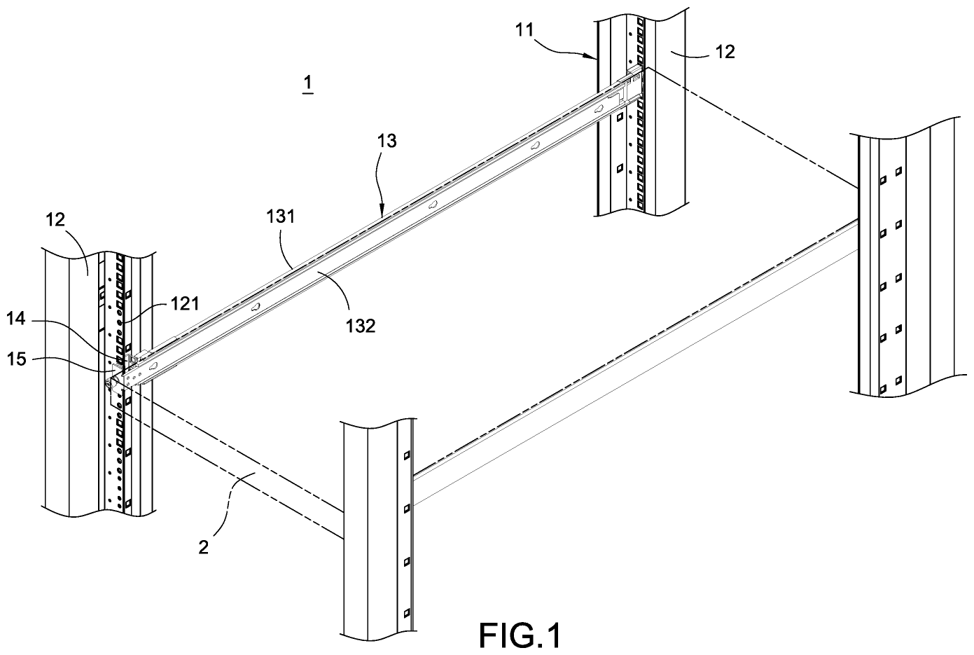

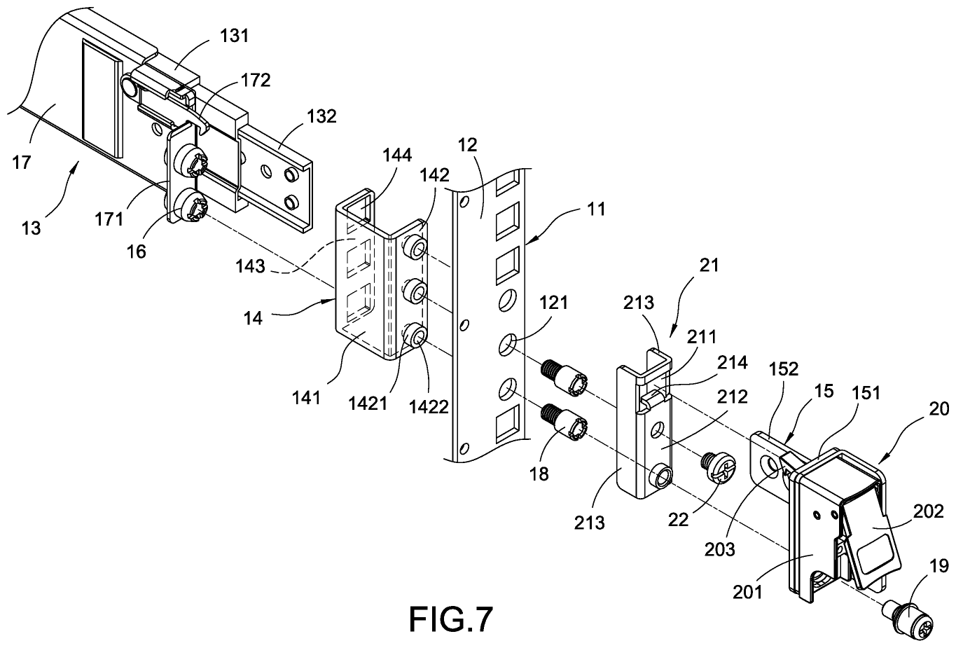

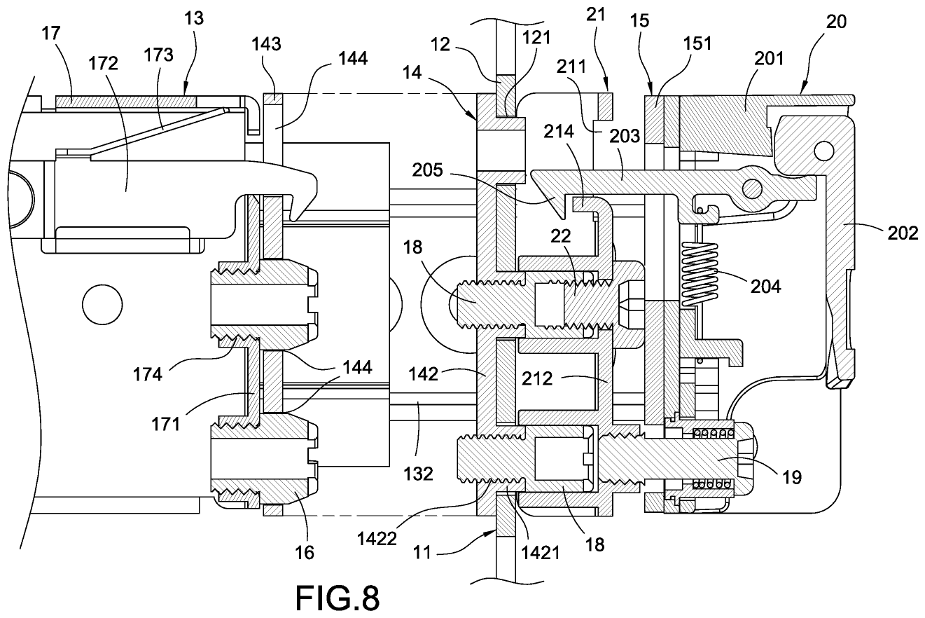

As shown in FIG. 1, the present invention provides a server 1 having a slide rail fastening structure. The server 1 includes a rack 11, a support 14 and a bracket 15. The support 14 and the bracket 15 together form a slide rail fastening structure. In the embodiment shown in FIGS. 7 and 8, the server 1 further includes a locking structure 20, a connection member 21 and/or other suitable parts.

In the embodiment shown in FIG. 1, the rack 11 includes four pillars 12 and two slide rail assemblies 13. Each slide rail assembly is mounted between two corresponding pillars 12, so that the two slide rail assemblies 13 constitute a chassis 2. The chassis 2 is movable along the slide rail assemblies 13 with respect to the rack 11. Each pillar 12 includes a plurality of round holes 121 spaced apart from each other. Each slide rail assembly 13 includes an outer slide rail 131 and an inner slide rail 132 slidable with respect to the outer slide rail 131. Only one pillar and only one slide rail assembly 13 mounted thereto will be described hereinafter for convenience and simplicity.

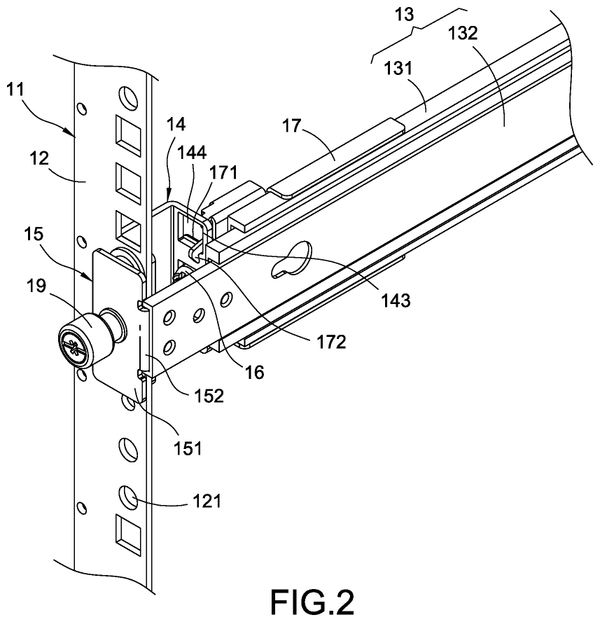

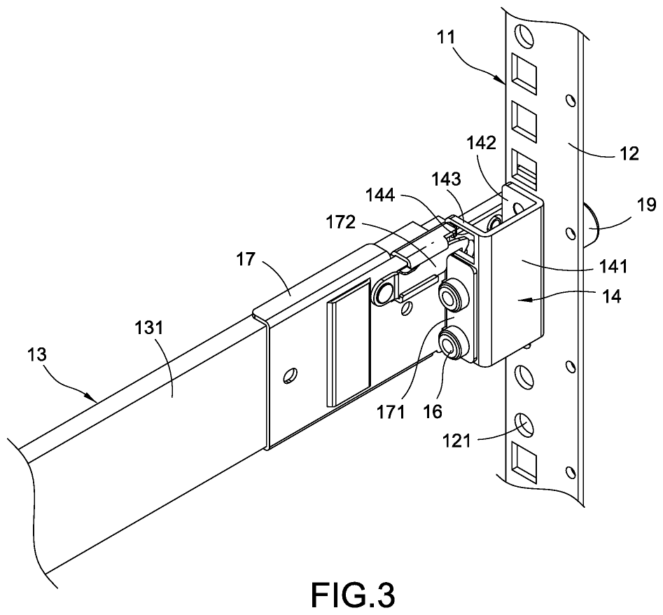

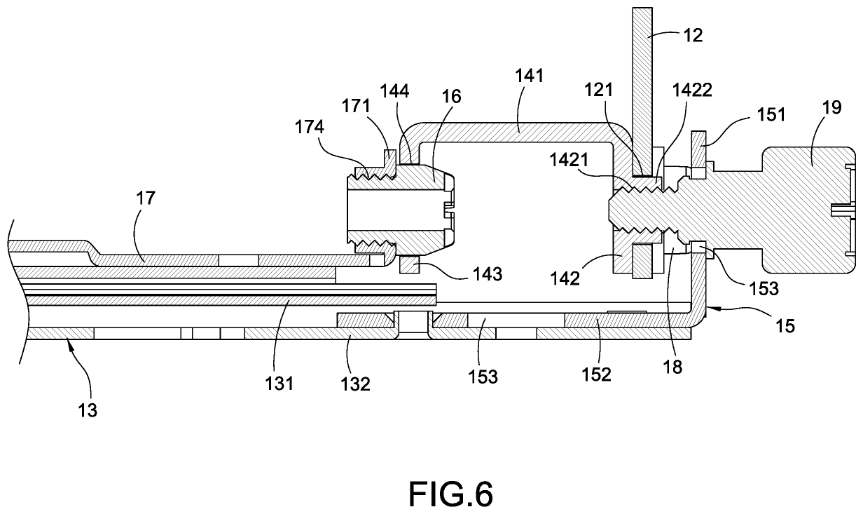

Referring to FIGS. 2 to 6, the support 14 includes a body 141 and a first plate 142 and a second plate 143 connected to the body 141 at two sides thereof. The support 14 is substantially of U shape. The first plate 142 is fixed to at least one round hole 121 of one of the pillars 12. The second plate 143 includes a plurality of openings 144. The opening 144 has a shape different from the round hole 121 and is used to position the slide rail assembly 13. In the embodiment shown in the drawings, the opening 144 is preferably of square shape. However, in alternative embodiments, the opening 144 has an oval shape or other suitable shape; the present invention is not limited in this regard.

The bracket 15 includes a first board 151 and a second board 152 perpendicularly connected to the first board 151. The bracket 15 is substantially of L shape. The first board 151 is arranged corresponding to the first plate 142, the second board 152 is arranged parallel to the slide rail assembly 13 and assembled to one end of the slide rail assembly 13, and thereby the bracket 15 and this end (the inner slide rail 132) can move together with respect to the rack 11.

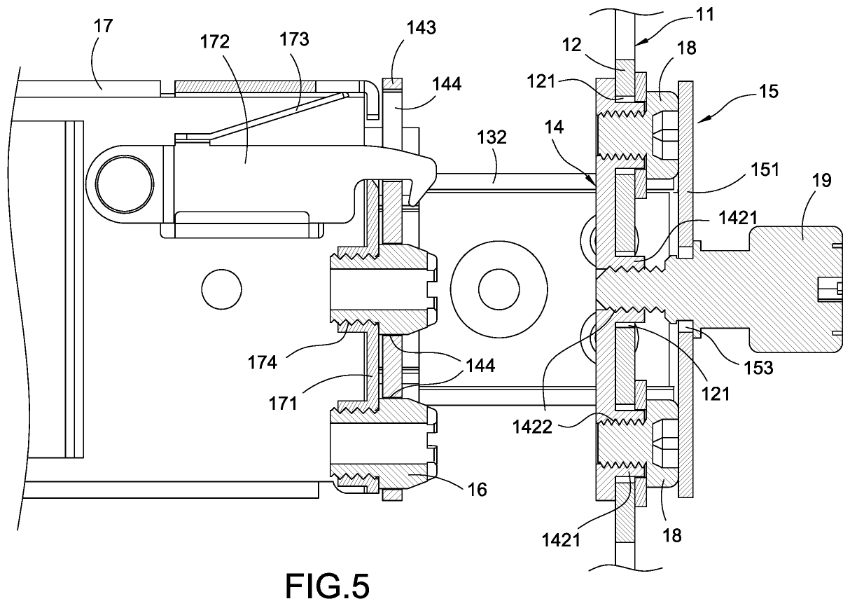

The slide rail assembly 13 further includes a fixing plate 171, a resilient hook 172 and an elastic element 16. The fixing plate 171 includes a plurality of ports 174, the resilient hook 172 is disposed adjacent to the fixing plate 171, and the elastic element 16 is fixed to any of the ports 174. The resilient hook 172 is arranged corresponding to and detachably engaged with one of the openings 144 of the second plate 143, so that the slide rail assembly 13 is fixed to the pillar 12 by means of the support 14. In detail, the present embodiment further includes a coupling member 17 coupled to an outer lateral surface of the slide rail assembly 13, the fixing plate 171 is preferably bent from one end of the coupling member 17, one end of the resilient hook 172 is pivotally fixed to the coupling member 17, and the other end of the resilient hook 172 protrudes beyond the fixing plate 171 to be engaged with the corresponding opening 144. As shown in FIG. 5, the resilient hook 172 is kept engaged with the opening 144 of the second plate 143 by means of a resilient plate 173 connected to the resilient hook 172. Moreover, a top end of the elastic element 16 is inserted and fixed in another opening 144, and thereby the slide rail assembly 13 is securely fastened to the second plate 143 of the support 14. The elastic element 16 and the resilient hook 172 are disposed apart from each other and disposed corresponding to the respective openings 144.

The first plate 142 further includes a plurality of protruding flanges 1421 and a plurality of through holes 1422 penetrating the respective protruding flanges 1421, and the protruding flanges 1421 are inserted and engaged with the respective round holes 121. Fastening elements 18 such as screws or bolts are inserted through the respective round holes 121 and the respective through holes 1422 so as to fix the support 14 to the pillar 12. Accordingly, the slide rail assembly 13 can be fixed to the pillar 12 by means of the first plate 142 and the second plate 143 having different shaped positioning holes (i.e. the round protruding flanges 1421 and the openings 144).

In the present embodiment, the support 14 preferably has three protruding flanges 1421 of round shape and three openings 144. The three protruding flanges 1421 and the three openings 144 are arranged corresponding to three round holes 121 of the pillar 12, so that the protruding flanges 1421 are fixed to the pillar 12, and the openings 144 are fixed to the slide rail assembly 13. In the present embodiment, the support 14 and/or the bracket 15 are sized to substantially cover an area of the three round holes 121, so that the support 14 and the bracket 15 can efficiently fix the slide rail assembly 13. In alternative embodiments, the support 14 and/or the bracket 15 can be sized to cover an area larger than or smaller than the area of the three round holes 121, and configuration may vary according to requirement. By using the support 14 and the bracket 15, the slide rail assembly 13 and the chassis 2 of different specifications can be assembled to the rack 11 without changing the present structure (the round holes 121 or different shaped holes) of the rack 11, so assembling is fast and easy, and the slide rail fastening structure (i.e. the support 14 and the bracket 15) is simple, thereby allowing for easy manufacture at low costs.

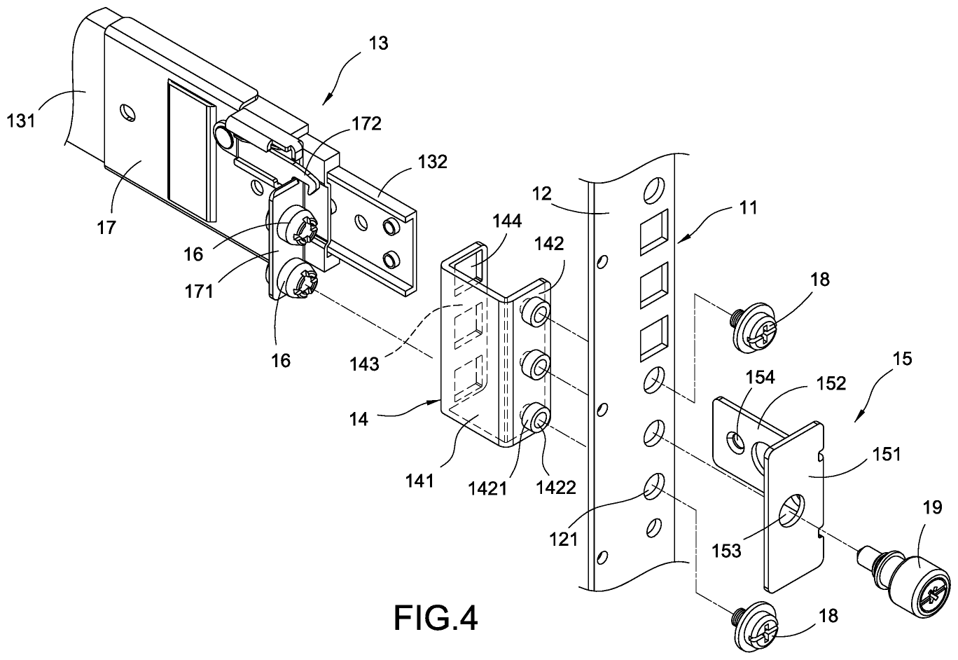

In order to prevent the slide rail assembly 13 and the chassis 2 from being accidentally detached from the rack 11, the present embodiment further includes a fixing element 19 for fastening the first board 151 to the pillar 12, so that the bracket 15 and the slide rail assembly 13 can be securely fastened to the pillar 12. In FIGS. 4 and 5, the fixing element 19 is, for example, a screw, a bolt or other suitable elements for fastening purpose. The first board 151 includes at least one open hole 153, the second board 152 includes at least one open hole 154, and the fixing element 19 is inserted through the open hole 153 of the first board 151 to be fastened to the pillar 12, and the fastening element 18 is inserted through the open hole 154 to be fastened to the inner slide rail 132. When the fixing element 19 is inserted through the first board 151 and fastened to the through hole 1422 of the first plate 142, the fastening element 18 is fastened more tightly to enhance a fastening effect between the slide rail assembly 13 and the pillar 12.

Please refer to FIGS. 7 and 8 for a perspective view and a cross-sectional view according to the second embodiment of the present invention. This embodiment further includes a locking structure 20 fixed to the first board 151 and also includes a connection member 21 disposed between the bracket 15 and the pillar 12. The locking structure 20 is fastened to the pillar 12 to keep the slide rail assembly 13 locked and allows an operator to use his fingers to withdraw or push back the chassis 2. In the drawings, the locking structure 20 includes a housing 201, a handle 202 pivotally rotatable with respect to the housing 201, a fastening hook 203 operatively connected to the handle 202, and a resilient element 204 for restoring the fastening hook 203 to its initial position.

The connection member 21 includes a fastening hole 211 disposed corresponding to the fastening hook 203, and the fastening hook 203 is rotatable to be fastened to the fastening hole 211. The connection member 21 includes a flat plate 212, two bent portions 213 connected to the flat plate 212, and an inverse hook 214 extended toward the bent portions 213. The inverse hook 214 is detachably engaged with the fastening hook 203, so that the locking structure 20 is fastened to the pillar 12. Side edges of the two bent portions 213 are in contact with the pillar 12, and a fastening element 22 is inserted through the flat plate 212 to fasten the connection member 21 to the pillar 12.

The locking structure 20 is operated by the following way. When the handle 202 is rotated to drive rotation of the fastening hook 203. An edge of the handle 202 pushes a bottom of the fastening hook 203, so that a hook portion 205 is tilted upwards to be detached from the inverse hook 214 of the connection member 21. When the operator continues to exert a force to the handle 202 to pull it in a direction away from the rack 11, the bracket 15 and the inner slide rail 132 can be pulled away from the chassis 2. At this time, the resilient element 204 stretches and stores a potential energy for restoring the fastening hook 203 to its initial position. When the operator releases the handle 202, the fastening hook 203 is restored by the resilient element 204, so the hook portion 205 returns to its original position, and then the operator can push back the chassis 2. The hook portion 205 has a slope (not labelled), so that the hook portion 205 can be smoothly restored to its original position and engaged with the inverse hook 214 to achieve a locked state.

This embodiment includes the fixing element 19 to fix the locking structure 20 to the connection member 21 (the pillar 12). By this way, the slide rail assembly 13 can be securely fastened to the pillar 12.

It is to be understood that the above descriptions are merely the preferable embodiment of the present invention and are not intended to limit the scope of the present invention. Equivalent changes and modifications made in the spirit of the present invention are regarded as falling within the scope of the present invention.

What is claimed is:

1. A server having a slide rail fastening structure, comprising:
a rack, the rack including two pillars and a slide rail assembly arranged longitudinally with respect to the rack and mounted to the two pillars, each pillar including a plurality of round holes spaced apart from each other;
a support, the support including a body and including a first plate and a second plate connected to the body at two sides thereof, the first plate being fixed to at least one of the round holes of a corresponding one of the pillars, the second plate including a plurality of openings, the opening having a shape different from the round hole and used to position the slide rail assembly; and
a bracket, the bracket including a first board and a second board perpendicularly connected to the first board, the first board being arranged corresponding to the first plate, the second board being arranged parallel to the slide rail assembly and assembled to one end of the slide rail assembly, thereby the bracket and this end moving together with respect to the rack.

2. The server having the slide rail fastening structure according to claim 1, wherein the slide rail assembly further includes a fixing plate, a resilient hook and an elastic element, the fixing plate includes a plurality of ports, the resilient hook is disposed adjacent to the fixing plate, and the elastic element is fixed to any of the ports.

3. The server having the slide rail fastening structure according to claim 2, wherein the resilient hook is arranged corresponding to and detachably engaged with one of the openings of the second plate, so that the slide rail assembly is fixed to the pillar by using the support.

4. The server having the slide rail fastening structure according to claim 2, further comprising a coupling member assembled to an outer lateral surface of the slide rail assembly, the fixing plate being bent from one end of the coupling member, one end of the resilient hook being pivotally fixed to the coupling member, the other end of the resilient hook protruding beyond the fixing plate.

5. The server having the slide rail fastening structure according to claim 2, wherein a top end of the elastic element is inserted and positioned in the opening.

6. The server having the slide rail fastening structure according to claim 2, wherein the elastic element and the resilient hook are spaced apart from each other and disposed corresponding to the respective openings.

7. The server having the slide rail fastening structure according to claim 1, wherein the first plate includes a plurality of protruding flanges and a plurality of through holes penetrating the respective protruding flanges, and the protruding flanges are inserted and engaged with the respective round holes.

8. The server having the slide rail fastening structure according to claim 7, further comprising a plurality of fastening elements, the fastening elements being inserted through the respective round holes and the respective through holes so as to fix the support to the pillar.

9. The server having the slide rail fastening structure according to claim 7, wherein the protruding flanges are of round shape to be engaged with the respective corresponding round holes.

10. The server having the slide rail fastening structure according to claim 1, wherein the slide rail assembly includes an outer slide rail and an inner slide rail slidable with respect to the outer slide rail, and the second board is assembled to the inner slide rail.

11. The server having the slide rail fastening structure according to claim 1, wherein each opening is of square shape.

12. The server having the slide rail fastening structure according to claim 1, further comprising a fixing element for fastening the first board to the pillar.

13. The server having the slide rail fastening structure according to claim 12, wherein the first board includes at least one open hole, the second board also includes at least one open hole, and the fixing element is inserted through the open hole of the first board to be fastened to the pillar.

14. The server having the slide rail fastening structure according to claim 1, wherein the support is of U shape, and the bracket is of L shape.

15. The server having the slide rail fastening structure according to claim 1, further comprising a locking structure fixed to the first board, the locking structure including a housing, a handle pivotally rotatable with respect to the housing, a fastening hook operatively connected to the handle, and a resilient element for restoring the fastening hook to its initial position.

16. The server having the slide rail fastening structure according to claim 15, further comprising a connection member disposed between the bracket and the pillar, the connection member including a fastening hole disposed corresponding to the fastening hook, the fastening hook being rotatable to be fastened to the fastening hole.

17. The server having the slide rail fastening structure according to claim 16, wherein the connection member includes a flat plate, two bent portions connected to the flat plate, and an inverse hook extended toward the bent portions, and the inverse hook is engaged with the fastening hook.

18. The server having the slide rail fastening structure according to claim 17, wherein side edges of the two bent portions are in contact with the pillar, and a fastening element is inserted through the flat plate to fasten the connection member to the pillar.
